(19) United States
(12) Patent Application Publication
(10) Pub. No.: US 2026/0136987 A1
(43) Pub. Date: May 14, 2026

(54) ELECTRONIC DEVICE

(71) Applicant: Innolux Corporation, Miaoli County (TW)

(72) Inventors: Mei-Yen Chen, Miaoli County (TW); Ju-Li Wang, Miaoli County (TW); Chung-Chun Cheng, Miaoli County (TW); Wen-Hsiang Liao, Miaoli County (TW); Pei-Yin Chou, Miaoli County (TW); Kun-Teng Ke, Miaoli County (TW)

(73) Assignee: Innolux Corporation, Miaoli County (TW)

(21) Appl. No.: 19/358,449

(22) Filed: Oct. 15, 2025

Related U.S. Application Data
(60) Provisional application No. 63/719,110, filed on Nov. 12, 2024.

(30) Foreign Application Priority Data
Jun. 26, 2025 (CN) 202510872328.0

(51) Int. Cl. H01L 23/31; H01L 23/00

(52) U.S. Cl. CPC H10W 74/121; H10W 70/652; H10W 72/29; H10W 72/981; H10W 74/15; H10W 90/724; H10W 90/734

(57) ABSTRACT

The present disclosure provides an electronic device including an electronic unit including a first conductive pad, a protective layer disposed on the electronic unit, a packaging layer surrounding the electronic unit and the protective layer, a conductive component disposed in the protective layer and overlapped with the first conductive pad, a bonding component disposed on the conductive component and overlapped with the first conductive pad, and an external component disposed on the bonding component and including a second conductive pad overlapped with the first conductive pad. The external component is electrically connected to the first conductive pad through the bonding component.

### CROSS-REFERENCE TO RELATED APPLICATION

This application claims the priority benefit of U.S. provisional application Ser. No. 63/719,110, filed on Nov. 12, 2024, and China application serial no. 202510872328.0, filed on Jun. 26, 2025. The entirety of each of the above-mentioned patent applications is hereby incorporated by reference herein and made a part of this specification.

### BACKGROUND

### Technical Field

The present invention relates to an electronic device, and particularly relates to an electronic device with good structural and electrical reliability.

### Description of Related Art

Generally, solder bumps/solder balls serve as signal connection bridges between electronic units and external components (such as circuit boards). The solder bumps/solder balls are used not only for signal transmission, but also to withstand internal stress or strain induced by the mismatch of the thermal expansion coefficient or warpage between the two components. When internal stress or strain is generated, it may cause cracking between the solder bumps/solder balls and the connection pads, thereby affecting the structural and electrical reliability of the electronic device.

### SUMMARY

According to an embodiment of the present disclosure, an electronic device includes an electronic unit, a protective layer, a packaging layer, a conductive component, a bonding component, and an external component. The electronic unit includes a first conductive pad. The protective layer is disposed on the electronic unit. The packaging layer surrounds the electronic unit and the protective layer. The conductive component is disposed in the protective layer and overlaps with the first conductive pad. The bonding component is disposed on the conductive component and overlaps with the first conductive pad. The external component is disposed on the bonding component and includes a second conductive pad. The external component is electrically connected to the first conductive pad through the bonding component and the conductive component. The second conductive pad overlaps with the first conductive pad.

### BRIEF DESCRIPTION OF THE DRAWINGS

The drawings are included for further understanding of the disclosure, and the drawings are incorporated into and constitute a part of the present specification. The drawings illustrate embodiments of the disclosure and, together with the description, are used to explain the principles of the disclosure.

FIG. 1A is a schematic cross-sectional view of an electronic device according to an embodiment of the present disclosure.

FIG. 1B is a schematic top view of a first conductive pad and a conductive component according to an embodiment of the present disclosure.

FIG. 1C is a schematic top view of a first conductive pad and a conductive component according to another embodiment of the present disclosure.

FIG. 2A to FIG. 2C are schematic cross-sectional views of a method for forming an electronic device according to an embodiment of the present disclosure.

FIG. 3A and FIG. 3B are schematic cross-sectional views of a method for forming an electronic device according to another embodiment of the present disclosure.

FIG. 4 is a schematic cross-sectional view of an electronic device according to another embodiment of the present disclosure.

FIG. 5 is a schematic cross-sectional view of an electronic device according to yet another embodiment of the present disclosure.

### DESCRIPTION OF THE EMBODIMENTS

The disclosure may be understood by referring to the following detailed description in conjunction with the drawings. It should be noted that, in order to allow readers to easily understand and for the sake of simplicity of the drawings, multiple drawings in the disclosure show just a part of a package structure, and specific elements in the drawings are not drawn according to actual proportions. In addition, the quantity and size of elements in the drawings are merely illustrative and are not intended to limit the scope of the disclosure. For example, for the sake of clarity, relative sizes, thicknesses, and positions of respective film layers, regions, and/or structures may be reduced or enlarged.

Throughout the present specification and the appended claims, certain terms are used to refer to specific elements. This document does not intend to distinguish elements that have the same function but different names. In the following description and/or the claims, words such as “have” and “comprise/include” are open-ended terms, and therefore should be interpreted as meaning “including but not limited to . . . ”. In the following description, the recitations such as “may be” are open-ended terms, and therefore should be interpreted as meaning “may be . . . , but not limited thereto”.

Directional terms mentioned in the present document, such as “upper,” “lower,” “front,” “rear,” “left,” “right,” and the like, are for referencing the directions shown in the drawings. Therefore, the directional terms used are for explanation and are not intended to limit the disclosure.

The terms “about,” “approximately,” “substantially,” or “roughly” mentioned in the present document generally represent being within 10% of a given value or range, or being within 5%, or 0.5% of the given value or range.

Features in different embodiments may be arbitrarily combined and used as long as they do not violate or conflict with the spirit of the invention, and simple equivalent changes and modifications made according to the present specification or the claims still fall within the scope of the disclosure. Furthermore, the terms “first,” “second,” and the like mentioned in the present specification or the claims are merely used to designate different elements or distinguish different embodiments or ranges, and are not intended to limit an upper or lower limit on the number of elements, nor are they intended to limit a manufacturing sequence or arrangement order of elements.

In the present disclosure, the thickness, length, and width may be obtained through a measurement using an optical microscope (OM) and/or a scanning electron microscope (SEM). Additionally, any two values or directions used for comparison may have a certain error.

The electronic device of the present disclosure may include power modules, semiconductor devices, semiconductor package devices, display devices, antenna devices, sensing devices, light-emitting devices, or tiled devices. The electronic device may include bendable or flexible electronic devices. The electronic device may include electronic elements. The electronic elements may include passive elements, active elements, or combinations thereof, such as capacitors, resistors, inductors, variable capacitors, filters, diodes, transistors, sensors, micro-electro-mechanical system (MEMS) elements, or liquid crystal chips. The method for manufacturing the electronic devices may be applied to, for example, a wafer-level package (WLP) process or a panel-level package (PLP) process, and may be a chip-first process or a chip-last process, which will be described in further detail below. The electronic device as referred to in the present disclosure may include system on package (SoC), system in package (SiP), antenna in package (AiP), co-packaged optics (CPO), or combinations thereof.

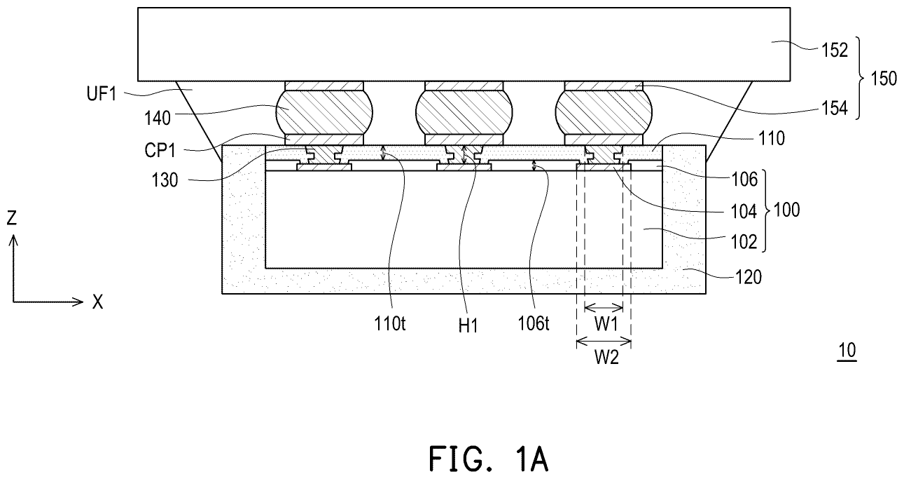

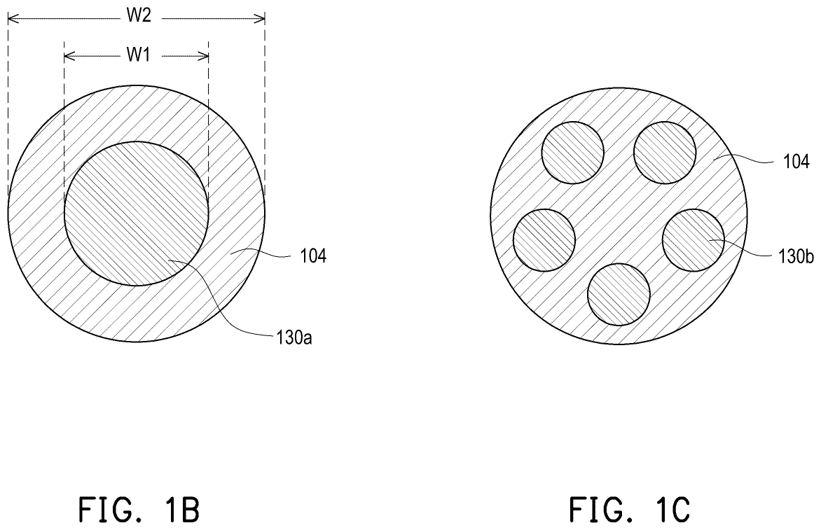

FIG. 1A is a schematic cross-sectional view of an electronic device according to an embodiment of the present disclosure. FIG. 1B is a schematic top view of a first conductive pad and a conductive component according to an embodiment of the present disclosure. FIG. 1C is a schematic top view of a first conductive pad and a conductive component according to another embodiment of the present disclosure.

Referring to FIG. 1A, the electronic device 10 includes an electronic unit 100, a protective layer 110, a packaging layer 120, a conductive component 130, a bonding component 140, and an external component 150.

In the present embodiment, the electronic unit 100 may include an electronic element 102, first conductive pads 104, and a passivation layer 106. The electronic element 102 may include a chip (e.g., a known good die (KGD)), a diode, an antenna, a sensor, a structure or an element formed through semiconductor-related processes, or a structure or an element disposed on a substrate and formed through semiconductor-related processes. The first conductive pads 104 may be disposed on the electronic element 102 and electrically connected to the electronic element 102. The first conductive pad 104 may be a signal input-output pad. The first conductive pad 104 may include any suitable conductive material, such as copper (Cu), aluminum (Al), nickel (Ni), molybdenum (Mo), titanium (Ti), gold (Au), alloys or combinations thereof. The passivation layer 106 may be disposed on the electronic element 102 and cover the first conductive pads 104, and the passivation layer 106 may have openings that expose a portion of the first conductive pads 104. The passivation layer 106 may be, for example, silicon oxide, silicon nitride, silicon oxynitride, photosensitive polyimide (PSPI), polybenzoxazole (PBO), benzocyclobutene (BCB), or other suitable dielectric materials.

The protective layer 110 is disposed on the electronic unit 100. In the present embodiment, the protective layer 110 fills into the openings of the passivation layer 106 that expose the first conductive pads 104. The protective layer 110 may have dielectric characteristics and may provide sufficient isolation characteristics, such as being able to withstand the breakdown voltage of components. According to some embodiments, the thickness 110t of the protective layer 110 overlapped with the bonding component 140 is at least 4 times greater than the thickness 106t of the passivation layer 106 to withstand the breakdown voltage of components. The material of the protective layer 110 may include an organic material or an inorganic material. For example, the material of the protective layer 110 may be Ajinomoto build-up film (ABF) resin or PSPI. In some embodiments, the Young's modulus of the protective layer 110 may range from 2 GPa to 30 GPa. The Young's modulus as referred to in the present disclosure may be obtained by measuring the stress-strain curve of a sample through a universal testing machine, for example, may be measured according to ASTM-D882 or other suitable standard methods. In some embodiments, the tensile strength of the protective layer 110 may range from 60 MPa to 180 MPa. The tensile strength as referred to in the present disclosure may be measured according to ASTM-D882 or other suitable standard methods. In some embodiments, the elongation of the protective layer 110 may range from 0.5% to 70%. The elongation as referred to in the present disclosure may be measured according to ASTM-D882 or other suitable standard methods.

The packaging layer 120 surrounds the electronic unit 100 and the protective layer 110. As shown in FIG. 1A, the packaging layer 120 may be directly in contact with the side surface of the electronic unit 100 and the side surface of the protective layer 110. The packaging layer 120 may provide the electronic unit 100 and/or the protective layer 110 with effects such as moisture resistance or dust resistance, thereby improving the reliability of the electronic device 10. In some embodiments, the material of the packaging layer 120 may be an insulation material. For example, the material of the packaging layer 120 may include silicon oxide, silicon nitride, silicon oxynitride, polymer, or epoxy molding compound (EMC).

The conductive components 130 are disposed in the protective layer 110 and overlap with the first conductive pads 104. In the present embodiment, the conductive components 130 may be electrically connected to the first conductive pads 104. The conductive component 130 may include any suitable conductive material, for example, Cu, Al, Ni, Mo, Ti, alloys or combinations thereof.

In some embodiments, the conductive component 130 may include an upper surface and a lower surface opposite to each other in the vertical direction (e.g., in the Z direction), and a ratio of a size (e.g., width W1) of the upper surface of the conductive component 130 in the horizontal direction (e.g., in the X direction) to a depth (e.g., height H1) of the conductive component 130 in the vertical direction may be greater than 1. In some embodiments, the width W1 of the upper surface of the conductive component 130 in the X direction may be smaller than the width W2 of the upper surface of the first conductive pad 104 in the X direction. In some embodiments, in the cross-sectional direction, the contour of the conductive component 130 may include trapezoidal, inverted trapezoidal, columnar, or I-shaped (as shown in FIG. 1A). In some embodiments, in the top view direction, the contour of the conductive component 130 may include circular, elliptical, or polygonal. For example, in the top view direction, the contour of the conductive component 130a or the conductive component 130b may be circular as shown in FIG. 1B or FIG. 1C. In the embodiment where the contour of the conductive component 130 in the top view direction is polygonal, the contour of the conductive component 130 in the top view direction may be, for example, a rectangle with chamfered or rounded corners. In some embodiments, the number of the conductive component 130 may be equal to or larger than one on each first conductive pad 104. For example, as shown in FIG. 1B, the number of the conductive component 130a may be one on each first conductive pad 104, or as shown in FIG. 1C, the number of the conductive component 130b may be plural on each first conductive pad 104. For example, along the Z direction, the number of the conductive components 130b in the orthogonal projection on the first conductive pad 104 may range from 2 to 10.

The size of the conductive component 130 is mainly considered the size of its bottom portion (e.g., the horizontal area in contact with the first conductive pad 104), which is the actual contact region for signal transmission. The size of the conductive component 130 is first defined by the current density required by the semiconductor component, typically checked through signal integrity/power integrity simulation for each package. To ensure sufficient contact area is obtained on the conductive component 130, the bottom diameter of the conductive component 130 may be greater than 10 μm to ensure good contact condition. In some embodiments, the total horizontal area of the conductive components 130 in contact with the first conductive pad 104 may be approximately 50% or more of the horizontal area of the first conductive pad 104. For example, as shown in FIG. 1B, the horizontal area of the conductive component 130a in contact with the first conductive pad 104 may be approximately 50% or more of the horizontal area of the first conductive pad 104, or as shown in FIG. 1C, the total horizontal area of the conductive components 130b in contact with the first conductive pad 104 may be approximately 50% or more of the horizontal area of the first conductive pad 104.

In some embodiments, a single large conductive component 130 may be separated into a plurality of small conductive components (e.g., the conductive components 130b shown in FIG. 1C), which may distribute current and stress from the bonding component 140 disposed on the conductive component 130, thereby preventing hot spots or stress from concentrating on the first conductive pad 104 or concentrating on a local region of the first conductive pad 104, resulting in cracking or rupture of the first conductive pad 104. On the other hand, small conductive components (e.g., the conductive components 130b) may prevent damage to the first conductive pad 104 by distributing surge current or electrostatic current, but are not limited thereto.

The bonding component 140 is disposed on the conductive component 130 and overlaps with the first conductive pad 104. In some embodiments, an offset of the geometric centers of the first conductive pad 104, the conductive component 130, and the bonding component 140 respective to a straight line may be less than 5% of the W1 to maintain good electrical performance. In detail, the first conductive pad 104 may have a geometric center. For example, in the projection direction, when the first conductive pad 104 and the conductive component 130 are circular, the geometric center of the first conductive pad 104 may be regarded as the center of the first conductive pad 104, and the geometric center of the conductive component 130 may be regarded as the center of the conductive component 130.

The electronic device 10 may be electrically connected to an external circuit through the bonding components 140. In some embodiments, the material of the bonding component 140 may include, for example, Sn, Ni, Au, Ag, Pd, Cu, Ga, alloys or combinations thereof. In some embodiments, the bonding component 140 may be, for example, a solder ball. In some embodiments, the bonding components 140 may be electrically connected to the conductive components 130 through connection pads CP1 disposed between the bonding component 140 and the conductive component 130. In this embodiment, the connection pads CP1 may be disposed on the protective layer 110 and overlap with the first conductive pads 104. The connection pad CP1 may include any suitable conductive material, such as Cu, Al, Ni, Mo, Ti, alloys or combinations thereof.

The external component 150 is disposed on the bonding components 140 and is electrically connected to the first conductive pads 104 through the bonding components 140 and the conductive components 130. In this embodiment, the external component 150 may include a circuit board 152 and second conductive pads 154 formed on the circuit board 152, wherein the second conductive pads 154 are bonded to the bonding components 140, so that the circuit board 152 is electrically connected to the electronic unit 100 through the second conductive pads 154, the bonding components 140, the connection pads CP1, and the conductive components 130. In this embodiment, the second conductive pads 154 overlap with the first conductive pads 104. The second conductive pads 154 may include any suitable conductive material, such as Cu, Al, Ni, Mo, Ti, alloys or combinations thereof. In some embodiments, the circuit board 152 may include packaging interposers with redistribution layers (RDL) of various materials, core substrates, or printed circuit boards (PCB).

In some embodiments, the electronic device 10 may further include a filling layer UF1 disposed between the external component 150 and the packaging layer 120 and surrounding the bonding components 140, the connection pads CP1, and the second conductive pads 154, thereby improving the structural and electrical reliability of the electronic device 10. In some embodiments, the filling layer UF1 may include an organic material or an inorganic material. The organic material may be a underfill or other suitable polymer materials for fixing the external component 150. The inorganic material may include silicon oxide, silicon nitride, or other suitable materials for fixing the external component 150 or adjusting the warpage of the electronic device 10. As shown in FIG. 1A, the filling layer UF1 may be in contact with the side surfaces of the bonding components 140, the connection pads CP1, and the second conductive pads 154.

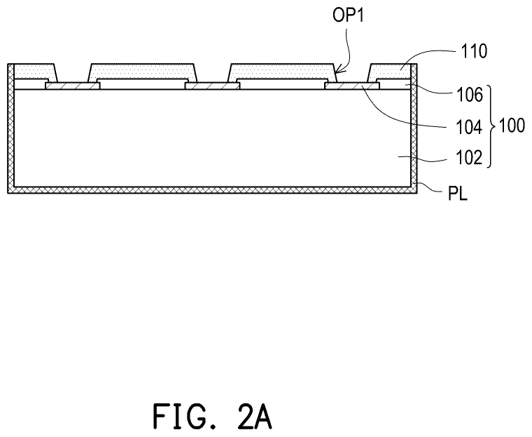

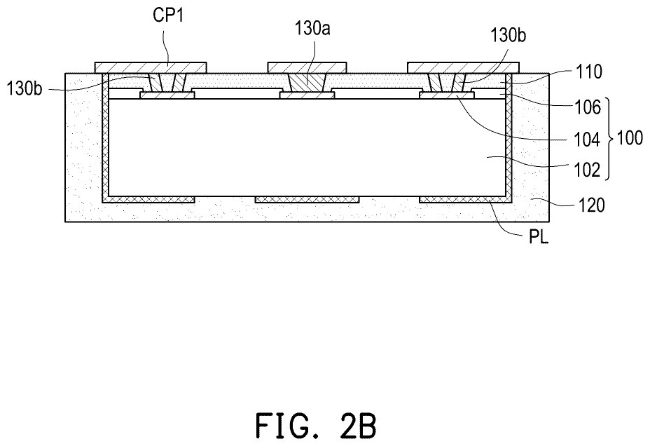

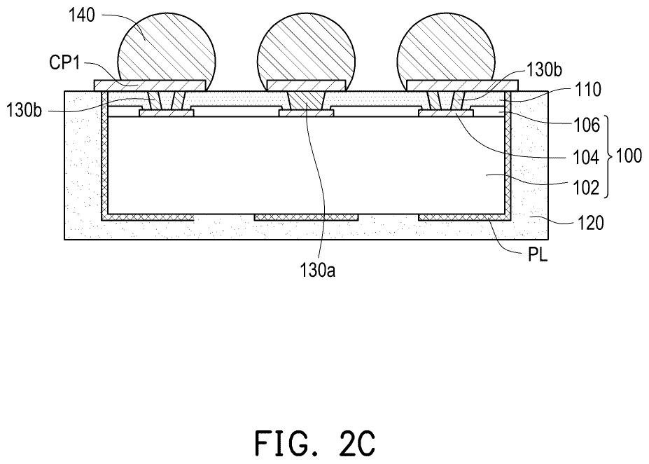

FIG. 2A to FIG. 2C are schematic cross-sectional views of a method for forming an electronic device according to an embodiment of the present disclosure. Hereinafter, some steps of the method for forming the electronic device 10 according to some embodiments of the present disclosure will be exemplified through FIG. 2A to FIG. 2C, and the steps may include wafer level packaging process or panel level packaging process, wherein the same or similar components are represented by the same or similar reference numerals or symbols, and will not be repeatedly described herein.

In some embodiments, the steps of forming the electronic device 10 may include the following steps.

First, referring to FIG. 2A, an electronic unit 100 is provided. The electronic unit 100 may include an electronic element 102, first conductive pads 104, and a passivation layer 106. Next, a protective layer 110 is formed on the electronic unit 100. The material of the protective layer 110 may include an organic material or an inorganic material. In the embodiment where the protective layer 110 is formed of the inorganic material (e.g., silicon oxide or silicon nitride), the protective layer 110 may be formed on the electronic unit 100 by, for example, chemical vapor deposition (CVD). In the embodiment where the protective layer 110 is formed of the organic material (e.g., dielectric polymer such as polyimide (PI)), the dielectric polymer in liquid form may be formed on the electronic unit 100 by spin coating or slit coating process, or the dielectric polymer in sheet form may be formed on the electronic unit 100 by lamination process.

Both liquid form and sheet form dielectric polymers will undergo a curing treatment subsequently. In some embodiments, the curing treatment may be performed by thermal curing and/or photocuring. To ensure quality, the curing rate has strict requirements for thermal, chemical, and environmental tolerance. The final curing rate is typically required to be greater than 95% or even higher to ensure good reliability performance. In some embodiments, to provide the protective layer 110 with appropriate rigidity, the curing treatment may be a curing process including multiple curing procedures.

Then, holes OP1 exposing the first conductive pads 104 are formed in the protective layer 110. In some embodiments, a laser drilling process or a photolithography process may be performed on the protective layer 110 to form the holes OP1 in the protective layer 110. Thereafter, a cleaning process is performed on the holes OP1 to remove residues on the first conductive pads 104. In some embodiments, the cleaning process may be performed by plasma, wet etching, dry etching, laser, combinations thereof, or other suitable processes to remove residues on the first conductive pads 104. In some embodiments, the plasma may include oxygen plasma. In other embodiments, carbon tetrafluoride (CF₄) with a content of 5-30 vol % may be introduced into the oxygen plasma to enhance the cleaning capability of the cleaning process. In some embodiments, after performing the cleaning process, automated optical inspection (AOI) may be used to identify the holes OP1 in which residues still exist. Next, laser repair rework is performed on the holes OP1 with residues to improve yield. In some embodiments, the sizes of the adjacent holes OP1 may be different from each other, or the ratio of the sizes between the holes OP1 in which the conductive components 130 connecting to the same signal are subsequently formed may be distributed between 0.8 and 1.2.

In this embodiment, as long as a sufficient effective contact area between the conductive component 130 subsequently formed in the hole OP1 and the first conductive pad 104 can be ensured, the hole OP1 may be of any shape. The shapes of the holes OP1 within the same electronic unit 100 may be the same as or different from each other. A plurality of holes on the same conductive component may have different shapes when needed. In this embodiment, the aspect ratio of the holes OP1 may be less than 1 (i.e., depth of hole OP1/diameter of hole OP1<1). The inclined angle of the sidewall of the hole OP1 may be greater than 85°.

Next, referring to FIG. 2A and FIG. 2B, conductive components (e.g., the conductive components 130 of FIG. 1A, the conductive component 130a of FIG. 1B, or the conductive components 130b of FIG. 1C) are formed in the holes OP1. In the embodiments shown in FIG. 2A and FIG. 2B, the conductive components with different densities may be disposed on the first conductive pads 104 at different positions. For example, the conductive components 130b with higher density and smaller size may be disposed on the first conductive pads 104 at the peripheral region of the electronic unit 100, while the conductive components 130a with lower density and larger size may be disposed on the first conductive pads 104 at the center of the electronic unit 100, which is beneficial for improving the structural and electrical reliability of the electronic device 10. Then, a packaging layer 120 surrounding the electronic unit 100 and the protective layer 110 is formed. Next, connection pads CP1 overlapped with the first conductive pads 104 and the conductive components 130a and 130b are formed on the protective layer 110. According to some embodiments, before providing the packaging layer 120, a promotion layer PL may be formed on the back surface and side surfaces of the electronic unit 100 to enhance the bonding force between the packaging layer 120 and the electronic unit 100. According to some embodiments, the promotion layer PL may be a discontinuous film layer, and the promotion layer PL may overlap with the first conductive pads 104 and the conductive components 130 for buffering stress. The promotion layer PL may include an organic material, such as polymer or epoxy resin. The Young's modulus of the promotion layer PL may be less than that of the packaging layer 120. According to some embodiments, the promotion layer PL may include a portion in which the heat dissipation particles are dispersed in the organic material, and the heat dissipation particles include graphene, metal particles, or any heat dissipation material or material with heat dissipation coefficient greater than that of the packaging layer 120.

Afterward, referring to FIG. 2C, bonding components 140 are formed on the connection pads CP1. In this embodiment, the bonding component 140 may cover the side surface of the connection pad CP1. The connection pad CP1 may contact the surface of the promotion layer PL and the packaging layer 120, so that the circuit of the electronic device can achieve a fan-out design. In some embodiments, after a reflow process, the bonding components 140 may cover the side surfaces of the connection pads CP1. Since the connection pads CP1 are covered by the bonding components 140, the connection pads CP1 may be embedded within the bonding components 140, thereby improving the shear stress or fatigue life of soldering. According to some embodiments, the conductive components 130a and 130b located in the protective layer 110 are beneficial for resisting shear stress.

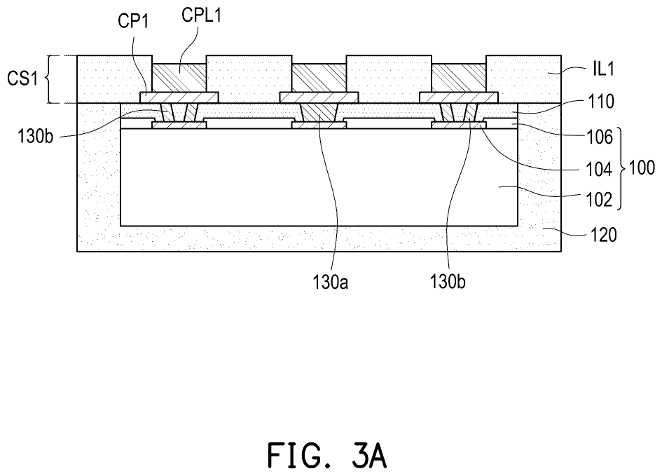

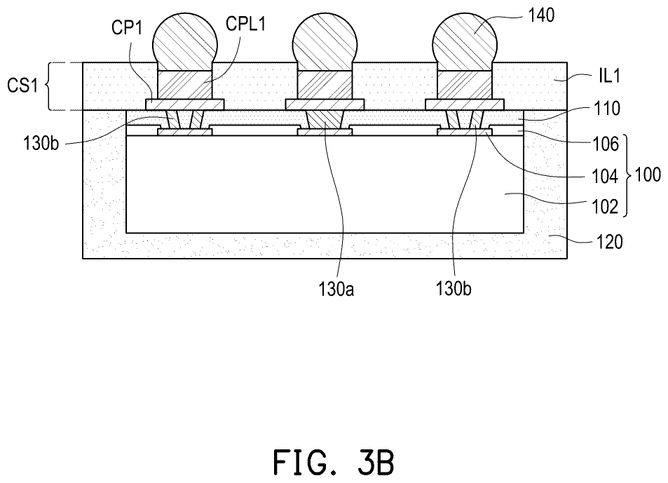

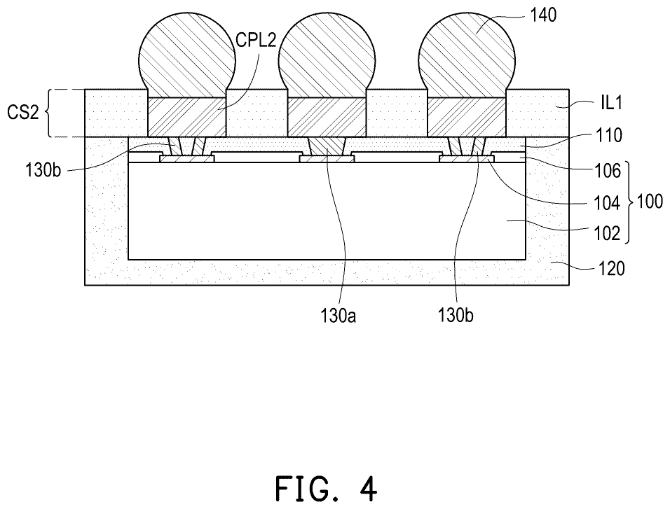

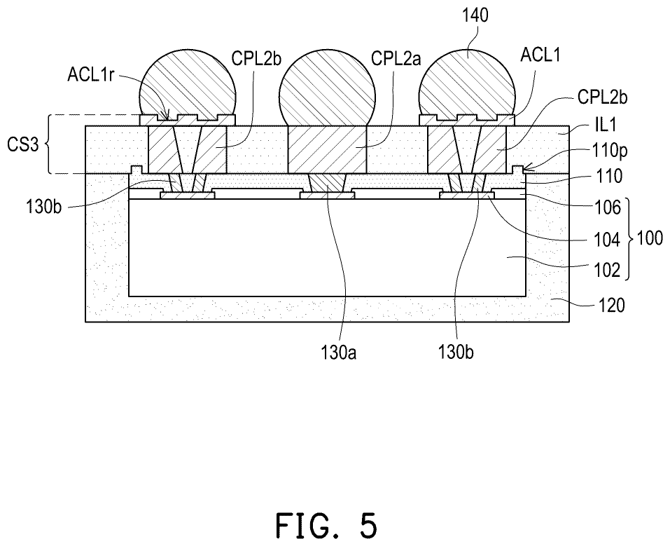

FIG. 3A and FIG. 3B are schematic cross-sectional views of a method for forming an electronic device according to another embodiment of the present disclosure. FIG. 4 is a schematic cross-sectional view of an electronic device according to another embodiment of the present disclosure. FIG. 5 is a schematic cross-sectional view of an electronic device according to yet another embodiment of the present disclosure.

Hereinafter, some steps of the method for forming the electronic device 10 according to other embodiments of the present disclosure will be exemplified through FIG. 3A and FIG. 3B, wherein the same or similar components are represented by the same or similar reference numerals or symbols, and will not be repeatedly described herein.

In other embodiments, the steps of forming the electronic device 10 may include the following steps.

First, referring to FIG. 3A, the electronic unit 100, the protective layer 110, the packaging layer 120, and the conductive components 130a and 130b may be provided, for example, through the steps shown in the aforementioned FIG. 2A and FIG. 2B.

Next, a circuit structure CS1 is provided on the protective layer 110. The circuit structure CS1 may include at least one of a connection pad CP1 and a conductive pillar CPL1, and at least one of the connection pad CP1 and the conductive pillar CPL1 may overlap with the first conductive pad 104 and may be electrically connected to the conductive components 130a and 130b. In this embodiment, the aforementioned process of forming the connection pads CP1 may be integrated into the process of forming the circuit structure CS1, that is, the connection pads CP1 may be included in the circuit structure CS1. In this embodiment, the circuit structure CS1 may include connection pads CP1 formed on the first conductive pads 104 and conductive pillars CPL1 formed on the connection pads CP1, wherein the connection pads CP1 may electrically connect the conductive pillars CPL1 to the conductive components 130a and 130b. The connection pad CP1 and the conductive pillar CPL1 may each include any suitable conductive material, such as Cu, Al, Ni, Mo, Ti, Ta, V, alloys or combinations thereof.

Along the Z direction, the orthogonal projection of at least one of the connection pad CP1 and the conductive pillar CPL1 on the first conductive pad 104 may be larger than the first conductive pad 104. In this embodiment, the orthogonal projection of the connection pad CP1 on the first conductive pad 104 may be larger than the first conductive pad 104.

The circuit structure CS1 may further include an insulation layer IL1 surrounding at least one of the connection pad CP1 and the conductive pillar CPL1 and extending onto the packaging layer 120. In this embodiment, the insulation layer IL1 may surround the connection pads CP1 and the conductive pillars CPL1 and extend onto the packaging layer 120. As shown in FIG. 3A, the insulation layer IL1 may be in contact with the side surfaces of the connection pads CP1 and the conductive pillars CPL1. The insulation layer IL1 may include an organic material or an inorganic material. The organic material includes polyimide (PI), poly-p-xylylene (also known as Parylene), BCB, epoxy, polycarbonate (PC), polyethylene terephthalate (PET), polyethylene naphthalate (PEN), polymer, or other suitable organic materials. The inorganic material includes silicon oxide, silicon nitride, silicon oxynitride, or other suitable inorganic materials.

In this embodiment, the conductive pillars CPL1 may be formed through the following steps. First, openings exposing the connection pads CP1 are formed in the insulation layer IL1. Next, conductive materials are filled into the openings to form the conductive pillars CPL1. In the embodiment where the conductive materials further cover on the insulation layer IL1, the conductive materials on the insulation layer IL1 may be further removed through a planarization process such as an etch back to form the conductive pillars CPL1. In this embodiment, the top surfaces of the conductive pillars CPL1 and the top surfaces of the insulation layer IL1 may have a height difference of, for example, about 4 μm to about 11 μm (e.g., the height difference generated by the aforementioned planarization process).

Then, referring to FIG. 3B, a bonding component 140 is formed on the circuit structure CS1. The aforementioned height difference causes the bonding surface between the bonding components 140 and the conductive pillars CPL1 to be displaced downward from the top surface of the insulation layer IL1. The size (e.g., height) of the conductive pillar CPL1 in the vertical direction may be in a range of 15 μm to 100 μm, 25 μm to 85 μm, or 30 μm to 70 μm, which is beneficial for improving structural and electrical reliability. For example, when the height of the conductive pillar CPL1 is greater, the fatigue life (in terms of cycles) of the solder joint in dual temperature cycling test may be extended. According to some embodiments, impedance considerations still need to be taken into account. If it exceeds 100 μm, the impedance may become too high, thereby affecting electrical performance.

At least one of the connection pad CP1 and the conductive pillar CPL1 is located between the bonding component 140 and the conductive component 130 and overlaps with the first conductive pad 104. In this embodiment, the connection pads CP1 and the conductive pillars CPL1 may be located between the bonding components 140 and the conductive components 130, and overlap with the first conductive pads 104 of the electronic unit 100, the conductive pillars CPL1, and the bonding components 140. In this embodiment, each conductive pillar CPL1 may overlap with a plurality of conductive components 130b (referring to FIG. 1C and FIG. 3B).

In some embodiments, the size (e.g., width) of the conductive pillar CPL1 in the horizontal direction may be greater than 80% of the diameter of the bonding component 140. In some embodiments, the size of the conductive component (e.g., the size of the conductive component 130a) may be equal to the width of the conductive pillar CPL1 minus 15 μm.

In some other embodiments, when the size (e.g., diameter) of the conductive pillar in the horizontal direction is greater than the size (e.g., diameter) of the conductive component in the horizontal direction, the connection pad disposed between the conductive component and the conductive pillar may be omitted. As shown in FIG. 4, when the diameter of the conductive pillar CPL2 is greater than the diameter of the conductive component 130a or the diameter of the hole in which the conductive components 130b are formed, the connection pad CP1, shown in FIG. 3B may be omitted. That is, in this embodiment, the circuit structure CS2 may include the conductive pillars CPL2 and the insulation layer IL1 surrounding the conductive pillars CPL2. The conductive pillars CPL2 of the circuit structure CS2 overlap with the conductive component 130a and overlaps with the conductive components 130b.

In some embodiments, the number of the conductive pillars CPL2 on each first conductive pad 104 may be equal to or larger than one. For example, as shown in FIG. 4, the number of the conductive pillar CPL2 on each first conductive pad 104 may be one, or as shown in FIG. 5, the number of the conductive pillars CPL2b on each first conductive pad 104 may be plural. For example, the number of the conductive pillars CPL2b in the orthogonal projection of the first conductive pad 104 may range from 2 to 10.

In the embodiment shown in FIG. 5, the circuit structure CS3 may include one conductive pillar CPL2a on one of the first conductive pads 104 and multiple conductive pillars CPL2b on another one of the first conductive pads 104. In this embodiment, conductive pillars with different densities may be disposed on the first conductive pads 104 at different positions. For example, the conductive pillars CPL2b with higher density and smaller size may be disposed on the first conductive pads 104 at the periphery of the electronic unit 100, while the conductive pillars CPL2a with lower density and larger size may be disposed on the first conductive pads 104 at the center of the electronic unit 100, which is beneficial for improving the structural and electrical reliability of the electronic device 10. In this embodiment, the insulation layer IL1 may include a portion between the multiple conductive pillars CPL2b. In some embodiments, the portion may overlap with a portion of the protective layer 110 between the conductive components 130b. In some embodiments, the periphery region surrounds the center region, and the periphery region is the area ⅕ of the electronic unit length away from the edge of the electronic unit.

In some embodiments, as shown in FIG. 5, the protective layer 110 has at least one protrusion 110p protruding toward the insulation layer IL1, and the circuit structure CS3 may further include auxiliary conductive layers ACL1 disposed on the insulation layer IL1. In this embodiment, the edge region of the protective layer 110 has at least one protrusion 110p protruding toward the insulation layer IL1, which can improve the bonding force with the circuit structure CS3. In this embodiment, the auxiliary conductive layer ACL1 may have recesses ACL1r and the bonding component 140 may extend into the recesses ACL1r. The auxiliary conductive layer ACL1 may include any suitable conductive material, such as Cu, Al, Ni, Mo, Ti, alloys or combinations thereof. In some embodiments, the auxiliary conductive layer ACL1 having the recesses ACL1r may be disposed between the bonding component 140 and the conductive pillars CPL2b in the corner region or peripheral region of the circuit structure CS3, which can be applicable to the situation where the stress on the corner or peripheral increases as the packaging size increases. For example, the structure shown in FIG. 5 may be applicable to large-size (>10 mm×10 mm) thin package (thickness<0.5 mm).

In summary, in the electronic device of the disclosed embodiments, the protective layer disposed on the electronic unit may be beneficial for mitigating the impact of external pressure on the electronic unit disposed below and/or the conductive components disposed therein, thereby resulting in the electronic device to have good structural and electrical reliability.

What is claimed is:

1. An electronic device, comprising:
an electronic unit comprising a first conductive pad;
a protective layer disposed on the electronic unit;
a packaging layer surrounding the electronic unit and the protective layer;
a conductive component disposed in the protective layer and overlapped with the first conductive pad;
a bonding component disposed on the conductive component and overlapped with the first conductive pad; and
an external component disposed on the bonding component and comprising a second conductive pad, wherein the external component is electrically connected to the first conductive pad through the bonding component and the conductive component, and the second conductive pad overlaps with the first conductive pad.

2. The electronic device according to claim 1, further comprising:
a circuit structure disposed on the protective layer and comprising at least one of a connection pad and a conductive pillar, wherein the at least one of the connection pad and the conductive pillar is located between the bonding component and the conductive component and overlaps with the first conductive pad.

3. The electronic device according to claim 2, wherein an orthogonal projection of the at least one of the connection pad and the conductive pillar on the first conductive pad is larger than the first conductive pad.

4. The electronic device according to claim 3, wherein the circuit structure further comprises an insulation layer surrounding the at least one of the connection pad and the conductive pillar and extending onto the packaging layer.

5. The electronic device according to claim 3, wherein the connection pad extends onto the packaging layer.

6. The electronic device according to claim 4, wherein the protective layer has a protrusion protruding toward the insulation layer.

7. The electronic device according to claim 4, wherein the circuit structure further comprises an auxiliary conductive layer disposed on the insulation layer and having a recess, the bonding component extending into the recess.

8. The electronic device according to claim 7, wherein the auxiliary conductive layer is disposed between the bonding component and the conductive pillar in a peripheral region of the circuit structure.

9. The electronic device according to claim 1, wherein the conductive component comprises an upper surface and a lower surface opposite to each other in a vertical direction, and a ratio of a size of the upper surface of the conductive component in a horizontal direction to a depth of the conductive component in the vertical direction is greater than 1.

10. The electronic device according to claim 1, wherein, in a top view direction, a contour of the conductive component comprises a circle, an ellipse, or a polygon.

11. The electronic device according to claim 1, wherein a Young's modulus of the protective layer ranges from 2 GPa to 30 GPa.

12. The electronic device according to claim 1, wherein a tensile strength of the protective layer ranges from 60 MPa to 180 MPa.

13. The electronic device according to claim 1, wherein an elongation of the protective layer ranges from 0.5% to 70%.

14. The electronic device according to claim 1, wherein a number of the conductive component on each first conductive pad is equal to or larger than one.

15. The electronic device according to claim 13, wherein a number of the conductive component disposed on the first conductive pad at a periphery of the electronic unit is greater than a number of the conductive component disposed on the first conductive pad at a center of the electronic unit.

16. The electronic device according to claim 1, wherein an offset of geometric centers of the first conductive pad, the conductive component, and the bonding component respective to a straight line is less than 5%.

17. The electronic device according to claim 1, wherein the conductive component comprises an upper surface and a lower surface opposite to each other in a vertical direction, and a size of the upper surface of the conductive component in a horizontal direction is smaller than a size of an upper surface of the first conductive pad adjacent to the lower surface of the conductive component in the horizontal direction.

18. The electronic device according to claim 1, wherein the electronic unit comprises a passivation layer, which the protective layer is formed thereon and covers the first conductive pad, and a thickness of the protective layer overlapped with the bonding component is at least 4 times greater than a thickness of the passivation layer.

19. The electronic device according to claim 1, further comprising:
a promotion layer disposed between the electronic unit and the packaging layer, wherein a Young's modulus of the promotion layer is smaller than a Young's modulus of the packaging layer.

20. The electronic device according to claim 19, wherein the promotion layer comprises an organic material and heat dissipation particles dispersed in the organic material, and a heat dissipation coefficient of the heat dissipation particles is greater than a heat dissipation coefficient of the packaging layer.
